(19) United States
(12) Patent Application Publication
(10) Pub. No.: US 2026/0262197 A1
(43) Pub. Date: Sep. 3, 2026

(54) COOLING ASSEMBLY

(71) Applicant: Lear Corporation, Southfield, MI (US)

(72) Inventors: Antoni Pujol Simon, Valls (ES); Ramon Sanchez Rovira, Valls (ES)

(21) Appl. No.: 19/067,043

(22) Filed: Feb. 28, 2025

(51) Int. Cl. H05K 7/20

(52) U.S. Cl. CPC H05K 7/20409

(57) ABSTRACT

A cooling system includes a conductive housing, one or more conductive fins extending from the conductive housing, and a conductive layer disposed between the conductive housing and the one or more conductive fins. In a first cooling configuration, the one or more conductive fins may be exposed to dissipate heat generated within the conductive housing via the conductive layer. In a second cooling configuration, the one or more conductive fins may be enclosed via a cover to dissipate heat generated within the housing via the conductive layer. Additionally, the one or more fins may be disposed within a channel extending from the conductive housing. The channel may be substantially U-shaped, and/or the one or more conductive fins may extend substantially perpendicular to the housing.

### TECHNICAL FIELD

The present disclosure generally relates to cooling assemblies, including cooling assemblies that may include one or more cooling configurations that may, for example, be used in reducing an internal temperature of a housing.

### BRIEF DESCRIPTION OF THE DRAWINGS

While the claims are not limited to a specific illustration, an appreciation of various aspects may be gained through a discussion of various examples. The drawings are not necessarily to scale, and certain features may be exaggerated or hidden to better illustrate and explain an innovative aspect of an example. Further, the exemplary illustrations described herein are not exhaustive or otherwise limiting, and embodiments are not restricted to the precise form and configuration shown in the drawings or disclosed in the following detailed description. Exemplary illustrations are described in detail by referring to the drawings as follows:

FIG. 1 is a top view generally illustrating an embodiment of a cooling assembly in the first cooling configuration according to teachings of the present disclosure.

FIG. 2 is a top view generally illustrating an embodiment of a cooling assembly in the second cooling configuration according to teachings of the present disclosure.

FIG. 3 is a perspective view generally illustrating an embodiment of a cooling assembly in the second cooling configuration according to teachings of the present disclosure.

FIG. 4 is a sectional-side view generally illustrating an embodiment of a cooling assembly in a second cooling configuration with an active cooling component connected according to teachings of the present disclosure.

FIG. 5 is a perspective-sectional view generally illustrating an embodiment of a cooling assembly having a conductive layer according to teachings of the present disclosure.

FIG. 6 is a flow diagram generally illustrating an embodiment of a method of cooling a housing according to teachings of the present disclosure.

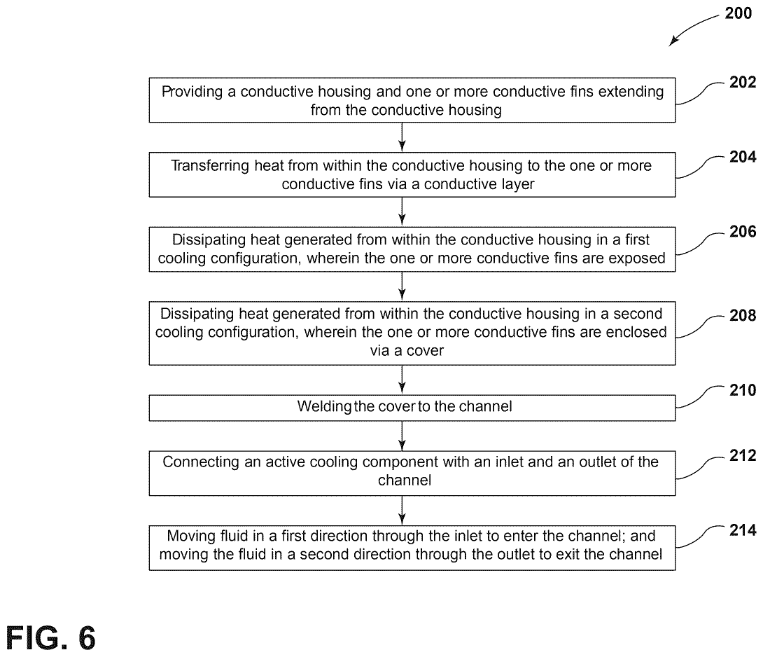

### DETAILED DESCRIPTION

Reference will now be made in detail to embodiments of the present disclosure, examples of which are described herein and illustrated in the accompanying drawings. While the present disclosure will be described in conjunction with embodiments and/or examples, they do not limit the present disclosure to these embodiments and/or examples. On the contrary, the present disclosure covers alternatives, modifications, and equivalents.

In examples, managing power distribution and providing protection in electronic systems is desired. Thermal management may ensure component reliability and longevity while meeting performance requirements. However, different compositions of electronic systems are contemplated that may generate varying temperatures. To accommodate the varying temperatures electronic systems, a scalable and/or modular cooling approach may be considered to alternate between a passive cooling arrangement and an active cooling arrangement.

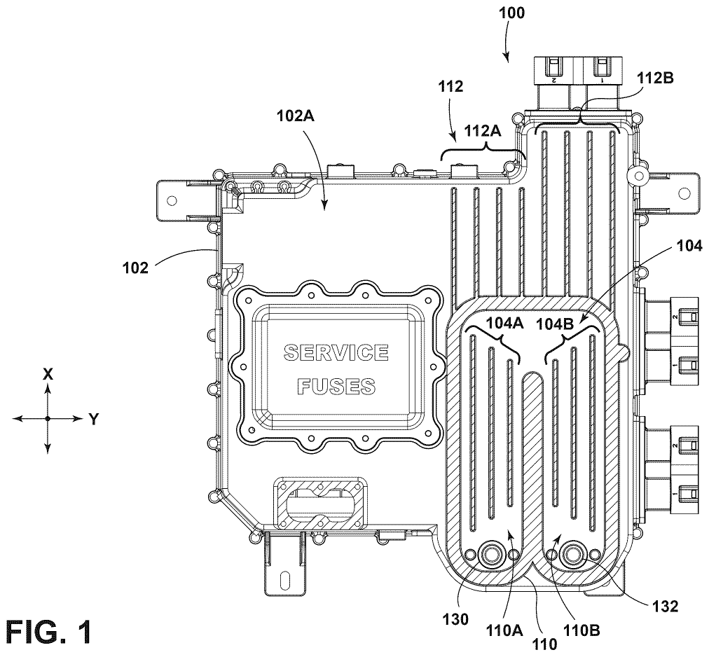

With embodiments such as generally illustrated in FIGS. 1, 2, and 3, a cooling system 100 may include a conductive housing 102 and/or one or more conductive fins 104. The cooling system 100 may be configured to dissipate heat generated from within the conductive housing 102 via the one or more conductive fins 104. One or more electrical components 106 may be disposed within the conductive housing 102 that may generate heat. The conductive housing 102 may shield/protect the one or more electrical components 106 from physical forces external to the conductive housing 102 (e.g., such as impact forces). For example and without limitations, the one or more electrical components 106 may comprise one or more of a variety of heat generating electrical components (e.g., such as relays, controllers, resistors, fuses, etc.) and/or any variety of connectors.

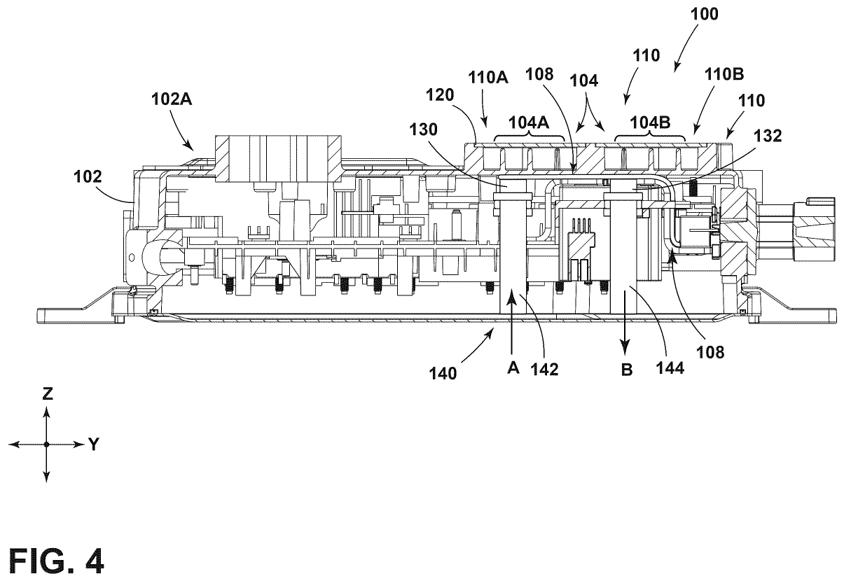

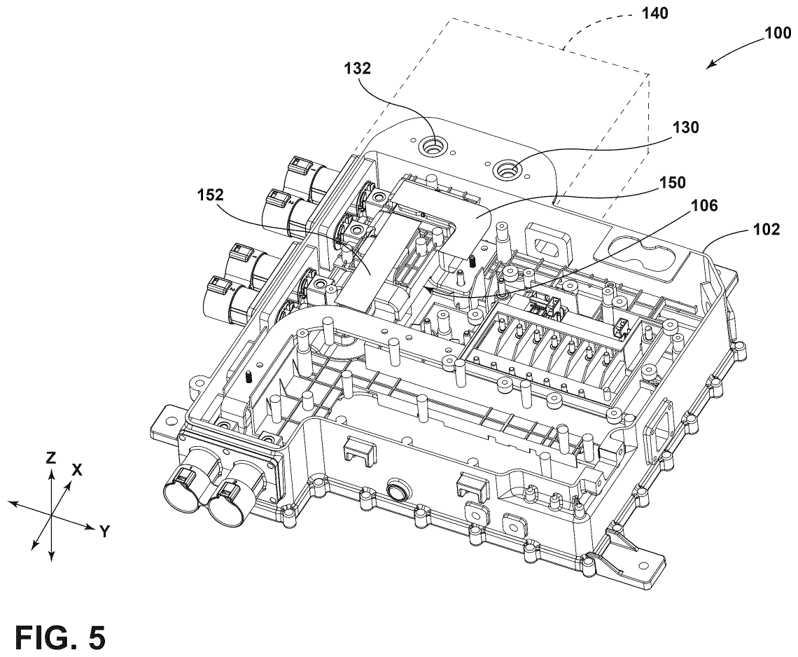

In examples, the conductive housing 102 may include one or more of a variety of shapes, sizes, and/or configurations. For example and without limitation, the conductive housing 102 may be generally rectangular shaped, and/or may include one or more of a variety of conductive materials (e.g. aluminum. Magnesium, steel, thermal conductive plastics, etc.). Additionally or alternatively, the conductive housing 102 may be comprised of a similar material as that of the one or more conductive fins 104. Further, the one or more electrical components 106 may increase an internal temperature of the conductive housing 102, which may be reduced via the conductive housing 102 and/or the one or more conductive fins 104. The conductive housing 102 may protect/shield the one or more electrical components 106 disposed at least partially within the conductive housing 102 from physical interference (e.g., damage). In various embodiments, the conductive housing 102 may be a sealed space where heat is transferred via a conductive layer 108 (e.g., see FIGS. 4 and 5).

With embodiments, the one or more conductive fins 104 may extend from the conductive housing 102 in one or more of a variety of directions. Further, the conductive housing 102 may include a top surface 102A (e.g., opposite a bottom surface 102B) which the one or more conductive fins 104 may extend outwardly therefrom. Additionally, to facilitate heat transfer between the conductive housing 102 and the one or more conductive fins 104, a conductive layer 108 may be disposed at least partially between the conductive housing 102 and the one or more conductive fins 104. The conductive layer 108 may be disposed about a variety of regions to dissipate heat proximate the one or more electrical components 106 through the one or more conductive fins 104, via the conductive layer 108.

In examples, the one or more conductive fins 104 may include one or more of a variety of shapes, sizes, and/or configurations. For example, the one or more conductive fins 104 may be generally planar and/or rectangular. In additional embodiments, the one or more conductive fins 104 may be curved. The one or more conductive fins 104 may include a variety of lengths, therefore the one or more conductive fins 104 may include varying surface areas for varying cooling rates. Additionally, the one or more conductive fins 104 may include a variety of conductive materials that may effectively transfer heat from the one or more electrical components 106 to the one or more conductive fins 104 via the conductive layer 108.

With embodiments, a channel 110 may be disposed on the top surface 102A of the conductive housing 102 and/or the channel 110 may extend outwardly from the top surface 102A (e.g., in the Z-direction and/or X-direction). The channel 110 may include a first portion 110A and/or a second portion 110B. The first portion 110A may be generally the same shape and/or size as the second portion 110B. In other embodiments, the first portion 110A may include a different shape and/or a different size than the second portion 110B. As can be seen in FIGS. 1, 2, and 3, the first portion 110A may be disposed substantially parallel to the second portion 110B. Further, the first portion 110A may be connected with the second portion 110B to form one continuous channel, which may be substantially U-shaped. The channel 110 may include any variety of shape that may dissipate heat generated within the conductive housing 102. Different sizes of the channel 110 may be contemplated depending on the desired rate of cooling (e.g. heat dissipation). For example, larger channels may be disposed proximate (e.g., in the Z-direction) electrical components 106 that generate greater heat than other electrical components 106. In this manner, various shapes and sizes may be considered for the one or more conductive fins 104 and/or the channel 110.

With examples, as generally shown in FIGS. 1, 2, and 3, the cooling system 100 may include one or more additional conductive fins 112 which may be disposed outside of the channel 110. The one or more additional conductive fins 112 may be disposed adjacent to the channel 110 and/or may extend from the top surface 102A of the conductive housing 102. Alternatively, the one or more additional conductive fins 112 may extend from any side(s) of the conductive housing 102 in regions where heat is to be dissipated. The one or more additional conductive fins 112 may include one or more of a variety of shapes, sizes, and/or configurations. As illustrated, the one or more additional conductive fins 112 may include a first plurality 112A and/or a second plurality 112B. Further, the first plurality 112A of the one or more additional conductive fins 112 may include a greater surface area (e.g., may be longer in the X-direction and/or may extend further from the conductive housing 102 in the Z-direction) than the second plurality 112B of the one or more additional conductive fins 112.

With embodiments, the cooling system 100 may be operable in a first cooling configuration (e.g., passive cooling) and/or a second cooling configuration (e.g., active cooling). The cooling system 100 may be configured to switch between the first cooling configuration and the second cooling configuration. For example, a cover 120 may be connected and/or removed from the conductive housing 102 to cool in an active capacity (e.g., with the cover 120) and in a passive capacity (e.g., without the cover 120). Further, the cover 120 may include conductive materials (e.g., metallics) and/or non-conductive materials. (e.g., plastics). In the second cooling configuration, a fluid may be retained within channel 110 via the cover 120.

In embodiments, when in the first cooling configuration, the one or more conductive fins 104 may be exposed (e.g., to the environment) and may dissipate/release heat accordingly. Further, in the second cooling configuration, the one or more conductive fins 104 may be enclosed via the cover 120 connected with the channel 110. As can be seen in FIG. 1, the cooling system 100 is shown in the first cooling configuration, where the cover 120 is not connected to the conductive housing 102 and/or the channel 110.

In examples, such as generally illustrated in FIG. 1, the cooling system 100 may dissipate heat (e.g., passively) in the first cooling configuration. The one or more conductive fins 104 and/or (ii) the channel 110 may be exposed to the outside environment to facilitate passive heat dissipation (e.g., convection cooling). Collectively, the one or more conductive fins 104, the channel 110, and/or the one or more additional conductive fins 112 may passively release heat via the conductive layer 108 and/or the conductive housing 102. For example, the one or more conductive fins 104, the channel 110, and/or the one or more additional conductive fins 112 may include a conductive material (e.g., such as aluminum) to transfer heat from within the conductive housing 102, through the conductive layer 108, and released into the exterior air via the one or more conductive fins 104, the channel 110, and/or the one or more additional conductive fins 112. With embodiments, the first cooling configuration may not include liquid-cooling and/or fans to actively move air proximate the one or more conductive fins 104.

Further, when transitioning the cooling system 100 from the first cooling configuration to the second cooling configuration, the cover 120 may connect with the conductive housing 102 (e.g., the channel 110) in a selectively fixed manner. In some embodiments, the cover 120 may be welded (e.g., fixed) to the conductive housing 102, and/or in other embodiments, the cover 120 may be connected in a removable means, such that once the cover 120 is connected with the conductive housing 102, it may later be removed.

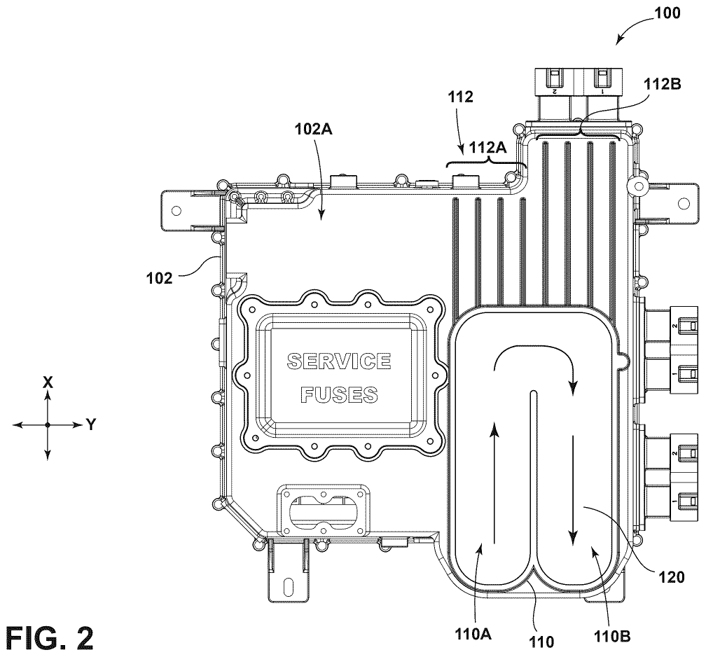

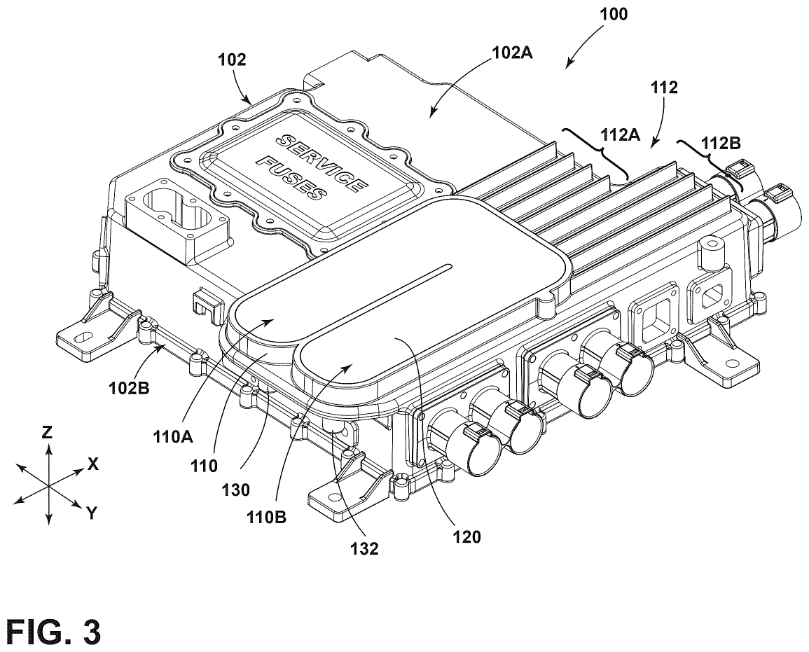

In embodiments, such as generally shown in FIGS. 2 and 3, the cooling system 100 may dissipate heat (e.g., actively) in the second cooling configuration (e.g., which may be a scaled/modular addition to the first cooling configuration). The second cooling configuration may provide a greater degree of temperature reduction (e.g., heat dissipation) than the first cooling configuration. Further, the second cooling configuration may include active cooling, which may include additional active cooling components (e.g., fans, fluids, etc.). The cover 120 may be selectively connected with the conductive housing 102 in one or more of a variety of manners. For example, the cover 120 may be welded to the channel 110 (e.g., the conductive housing 102) to seal the one or more conductive fins 104 within the channel 110. In embodiments, the cover 120 may be fixed to the channel 110 via Friction Stir Welding (FSW).

As illustrated in FIGS. 2 and 3, the cooling system 100 is shown in the second cooling configuration, where the cover 120 may be fixedly connected with the conductive housing 102 and/or the channel 110. For example and without limitation, the cover 120 may be substantially the same shape as the channel 110, such that a seal is formed when the cover 120 is fixed to the channel 110. Forming a seal about the cover 120 may prevent any variety of fluid from leaving the channel 110. As shown in FIGS. 1, 2, and 4, the cover may be generally U-shaped.

With embodiments, the channel 110 may include a fluid inlet 130 and/or a fluid outlet 132. The fluid inlet 130 and/or the fluid outlet 132 may route/direct fluid into and/or out of the conductive housing 102. With examples, when the cover 120 is connected to the channel 110, a fluid (e.g., a liquid coolant) may be disposed within the channel 110. The fluid may circulate from the fluid inlet 130, into the first portion 110A of the channel 110, to the second portion 100B of the channel 110, and out the fluid outlet 132. In this manner, the liquid may circulate about the first plurality 112A of the one or more conductive fins 104 within the first portion 110A of the channel 110 and/or the liquid may circulate about the second plurality 112B of the one or more conductive fins 104 within the second portion 110B of the channel 110.

In examples, such as illustrated in FIGS. 1, 3, and 5, the channel 110 may extend outward from the conductive housing 102 in one or more directions to connect externally (e.g., outside the conductive housing 102) with an active cooling component 140. For example and without limitation, the channel 110 may extend from the conductive housing 102 in the X-direction. The channel 110 may extend laterally outward from the conductive housing 102 for the fluid inlet 130 and/or the fluid outlet 132 to be disposed outside the conductive housing 102 (e.g., the fluid inlet 130 and/or the fluid outlet 132 may not be aligned in the Z-direction with the conductive housing 102). The fluid inlet 130 and/or the fluid outlet 132 may be offset in the X-direction from the conductive housing 102 so that the active cooling component 140 may be connected thereto without interfering with the conductive housing 102.

With embodiments, as shown in FIG. 4, the active cooling component 140 may be disposed adjacent to the conductive housing 102 for ease of connection and/or disconnection with the channel 110. Further, the active cooling component 140 may be configured for moving/transporting/circulating fluids (e.g., air, gas, liquid coolant, etc.) about the channel 110 to reduce an internal temperature of the conductive housing 102. The active cooling component 140 may be a variety of sizes having ports that connect with the fluid inlet 130 and/or the fluid outlet 132. For example, the active cooling component 140 may include a first conduit structure 142 and/or a second conduit structure 144, which may include one or more of a variety of shapes, sizes, and/or configurations. For example, the first conduit structure 142 and/or the second conduit structure 144 may be generally cylindrical. The first conduit structure 142 may transport fluid from the active cooling component 140 via a first fluid pathway (as shown by arrow A) to the fluid inlet 130 and into the first portion 110A of the channel 110. The fluid may travel from the first portion 110A of the channel 110 to the second portion 110B of the channel 110. Further, the fluid may travel out of the channel 110 via the fluid outlet 132 and back to the active cooling component 140 via the second conduit structure 144 on a second fluid pathway (shown by arrow B).

In embodiments, such as illustrated in FIGS. 4 and 5, the conductive layer 108 may transfer heat from the one or more electrical components 106 to the channel 110 in efforts to reduce an internal temperature of the conductive housing 102. Further, the conductive layer 108 may be disposed at least partially between (e.g., in the Z-direction) the one or more electrical components 106 and/or the top surface 102A of the conductive housing 102 (e.g., the channel 110). The conductive layer 108 may include one or portions disposed throughout the conductive housing 102. For example and without limitation, the conductive layer 108 may include a first portion 150 and/or a second portion 152. The first portion 150 and/or the second portion 152 may include a variety of shapes, sizes, and/or configurations. Further, the first portion 150 and/or the second portion 152 may be generally planar and/or may be curved. As can be seen in FIG. 5, the conductive layer 108 may be disposed proximate the channel 110 (e.g., in the X-direction and/or the Y-direction); and may be offset in the Z-direction. The conductive layer 108 may be in contact with the conductive housing 102 to increase the transfer of heat from within the conductive housing 102 to the channel 110.

With embodiments, a method 200 of cooling a housing may include providing a conductive housing 102 and/or one or more conductive fins 104 extending from the conductive housing 102 (step 202). The method 200 may further comprise transferring heat from within the conductive housing 102 to the one or more conductive fins 104 via a conductive layer 108 (step 204). Additionally, the method 200 of cooling a housing may include dissipating heat generated from within the conductive housing 102 in a first cooling configuration, wherein the one or more conductive fins 104 are exposed (step 206). In the first cooling configuration, the one or more electrical components 106 may generate heat within the conductive housing 102 which may be transferred to the one or more conductive fins 104 and/or the one or more additional conductive fins 1112 via the conductive layer 108. The method 200 may further comprise releasing heat from the one or more conductive fins 104 and/or the one or more additional conductive fins 112 to the open environment (e.g., where ambient air may circulate).

The method 200 may include dissipating heat generated from within the conductive housing 102 in a second cooling configuration, wherein the one or more conductive fins 104 are enclosed via a cover 120 (step 208). Further, the one or more conductive fins 104 may be disposed within a channel 110 extending from the conductive housing 102. In examples, the method 200 of cooling a conductive housing 102 may include welding the cover 120 to a channel 110 extending from the conductive housing 102 (step 210). The method 200 may additionally comprise connecting an active cooling component 140 with a fluid inlet 130 and/or a fluid outlet 132 of the channel 110 (step 212). Further, via the fluid inlet 130 and/or the fluid outlet 132, the method 200 may comprise moving a fluid in a first direction through the fluid inlet 130 to enter the channel 110; and moving the fluid in a second direction through the fluid outlet 132 to exit the channel 110 (step 214). The method may include connecting an active cooling component 140 with the channel 110 to move fluid through the channel 110 and reduce an internal temperature of the conductive housing 102.

The disclosure includes, without limitation, the following embodiments:
1. A cooling system, comprising: a conductive housing: one or more conductive fins extending from the housing; a conductive layer disposed between the housing and the one or more conductive fins; wherein, in a first cooling configuration, the one or more conductive fins are exposed to dissipate heat generated within the housing via the conductive layer; and wherein, in a second cooling configuration, the one or more conductive fins are enclosed via a cover to dissipate heat generated within the housing via the conductive layer.
2. The cooling system of embodiment 1, wherein the one or more conductive fins are disposed within a channel extending from the housing.
3. The cooling system according to any of the preceding embodiments, wherein the channel is substantially U-shaped.
4. The cooling system according to any of the preceding embodiments, wherein the one or more conductive fins extend substantially perpendicular to the housing.
5. The cooling system according to any of the preceding embodiments, wherein the housing includes aluminum.
6. The cooling system according to any of the preceding embodiments, wherein the conductive layer is substantially proximate at least one electrical component disposed within the housing.
7. The cooling system according to any of the preceding embodiments, wherein the conductive layer is in contact with at least one electrical component disposed within the housing.
8. The cooling system according to any of the preceding embodiments, wherein the channel includes a first portion connected with a second portion; the first portion includes a first conductive fin of the one or more conductive fins; and the second portion includes at second conductive fin of the one or more conductive fins.
9. The cooling system according to any of the preceding embodiments, wherein the first conductive fin is disposed parallel to the second conductive fin.
10. The cooling system according to any of the preceding embodiments, wherein a height of the one or more conductive fins is less than a height of the channel.
11. The cooling system according to any of the preceding embodiments, wherein the channel includes a first portion connected with a second portion, and the first portion includes a first plurality of conductive fins with varying lengths; and the second portion of the channel includes a second plurality of conductive fins with varying lengths.
12. The cooling system according to any of the preceding embodiments, wherein in the second cooling configuration, the cover is fixedly connected to the channel to seal the one or more conductive fins within the channel.
13. The cooling system according to any of the preceding embodiments, wherein the cover is welded to the channel via Friction Stir Welding (FSW).
14. The cooling system according to any of the preceding embodiments, wherein the one or more fins are disposed within a channel extending from the housing; the cover fluidly seals a first portion of the channel with a second portion of the channel; and the channel includes an inlet and an outlet to facilitate active cooling.
15. A method of cooling a housing, comprising: providing a conductive housing and one or more conductive fins extending from the conductive housing; transferring heat from within the conductive housing to the one or more conductive fins via a conductive layer; dissipating heat generated from within the conductive housing in a first cooling configuration, wherein the one or more conductive fins are exposed; and dissipating heat generated from within the conductive housing in a second cooling configuration, wherein the one or more conductive fins are enclosed via a cover.
16. The method according to any of the preceding embodiments, wherein the one or more conductive fins are disposed within a channel extending from the conductive housing.
17. The method according to any of the preceding embodiments, further comprising:
welding the cover to the channel via Friction Stir Welding (FSW).
18. The method according to any of the preceding embodiments, further comprising:
connecting an active cooling component with an inlet and an outlet of the channel.
19. The method according to any of the preceding embodiments, further comprising: moving a fluid in a first direction through the inlet to enter the channel; and moving the fluid in a second direction through the outlet to exit the channel.
20. The method according to any of the preceding embodiments, wherein the conductive layer is in contact with the conductive housing.

Various examples/embodiments are described herein for various apparatuses, systems, and/or methods. Numerous specific details are set forth to provide a thorough understanding of the overall structure, function, manufacture, and use of the examples/embodiments as described in the specification and illustrated in the accompanying drawings. It will be understood by those skilled in the art, however, that the examples/embodiments may be practiced without such specific details. In other instances, well-known operations, components, and elements have not been described in detail so as not to obscure the examples/embodiments described in the specification. Those of ordinary skill in the art will understand that the examples/embodiments described and illustrated herein are non-limiting examples, and thus it can be appreciated that the specific structural and functional details disclosed herein may be representative and do not necessarily limit the scope of the embodiments.

Reference throughout the specification to “examples, “in examples,” “with examples,” “various embodiments,” “with embodiments,” “in embodiments,” or “an embodiment,” or the like, means that a particular feature, structure, or characteristic described in connection with the example/embodiment is included in at least one embodiment. Thus, appearances of the phrases “examples, “in examples,” “with examples,” “in various embodiments,” “with embodiments,” “in embodiments,” or “an embodiment,” or the like, in places throughout the specification are not necessarily all referring to the same embodiment. Furthermore, the particular features, structures, or characteristics may be combined in any suitable manner in one or more examples/embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof.

It should be understood that references to a single element are not necessarily so limited and may include one or more of such element. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of examples/embodiments.

Joinder references (e.g., attached, coupled, connected, and the like) are to be construed broadly and may include intermediate members between a connection of elements, relative movement between elements, direct connections, indirect connections, fixed connections, movable connections, operative connections, indirect contact, and/or direct contact. As such, joinder references do not necessarily imply that two elements are directly connected/coupled and in fixed relation to each other. Connections of electrical components, if any, may include mechanical connections, electrical connections, wired connections, and/or wireless connections, among others. Uses of “e.g.” and “such as” in the specification are to be construed broadly and are used to provide non-limiting examples of embodiments of the disclosure, and the disclosure is not limited to such examples. Uses of “and” and “or” are to be construed broadly (e.g., to be treated as “and/or”). For example and without limitation, uses of “and” do not necessarily require all elements or features listed, and uses of “or” are inclusive unless such a construction would be illogical.

While processes, systems, and methods may be described herein in connection with one or more steps in a particular sequence, it should be understood that such methods may be practiced with the steps in a different order, with certain steps performed simultaneously, with additional steps, and/or with certain described steps omitted.

All matter contained in the above description or shown in the accompanying drawings shall be interpreted as illustrative only and not limiting. Changes in detail or structure may be made without departing from the present disclosure.

What is claimed is:

1. A cooling system, comprising:
a conductive housing:
one or more conductive fins extending from the housing; and
a conductive layer disposed between the housing and the one or more conductive fins;
wherein, in a first cooling configuration, the one or more conductive fins are exposed to dissipate heat generated within the housing via the conductive layer; and
wherein, in a second cooling configuration, the one or more conductive fins are enclosed via a cover to dissipate heat generated within the housing via the conductive layer.

2. The cooling system of claim 1, wherein the one or more conductive fins are disposed within a channel extending from the housing.

3. The cooling system of claim 2, wherein the channel is substantially U-shaped.

4. The cooling system of claim 2, wherein the one or more conductive fins extend substantially perpendicular to the housing.

5. The cooling system of claim 1, wherein the housing includes aluminum.

6. The cooling system of claim 1, wherein the conductive layer is substantially proximate at least one electrical component disposed within the housing.

7. The cooling system of claim 1, wherein the conductive layer is in contact with at least one electrical component disposed within the housing.

8. The cooling system of claim 2, wherein the channel includes a first portion connected with a second portion; the first portion includes a first conductive fin of the one or more conductive fins; and the second portion includes at second conductive fin of the one or more conductive fins.

9. The cooling system of claim 8, wherein the first conductive fin is disposed parallel to the second conductive fin.

10. The cooling system of claim 2, wherein a height of the one or more conductive fins is less than a height of the channel.

11. The cooling system of claim 2, wherein the channel includes a first portion connected with a second portion, and the first portion includes a first plurality of conductive fins with varying lengths; and the second portion of the channel includes a second plurality of conductive fins with varying lengths.

12. The cooling system of claim 2, wherein in the second cooling configuration, the cover is fixedly connected to the channel to seal the one or more conductive fins within the channel.

13. The cooling system of claim 2, wherein the cover is welded to the channel via Friction Stir Welding (FSW).

14. The cooling system of claim 12, wherein the one or more fins are disposed within a channel extending from the housing; the cover fluidly seals a first portion of the channel with a second portion of the channel; and the channel includes an inlet and an outlet to facilitate active cooling.

15. A method of cooling a housing, comprising:
providing a conductive housing and one or more conductive fins extending from the conductive housing;
transferring heat from within the conductive housing to the one or more conductive fins via a conductive layer;
dissipating heat generated from within the conductive housing in a first cooling configuration, wherein the one or more conductive fins are exposed; and
dissipating heat generated from within the conductive housing in a second cooling configuration, wherein the one or more conductive fins are enclosed via a cover.

16. The method of claim 15, wherein the one or more conductive fins are disposed within a channel extending from the conductive housing.

17. The method of claim 16, further comprising:
welding the cover to the channel via Friction Stir Welding (FSW).

18. The method of claim 17, further comprising:
connecting an active cooling component with an inlet and an outlet of the channel.

19. The method of claim 18, further comprising:
moving a fluid in a first direction through the inlet to enter the channel; and
moving the fluid in a second direction through the outlet to exit the channel.

20. The method of claim 19, wherein the conductive layer is in contact with the conductive housing.
